(19) United States
(12) Patent Application Publication
(10) Pub. No.: US 2023/0122914 A1
(43) Pub. Date: Apr. 20, 2023

(54) METHODS OF MANUFACTURING STRUCTURES FROM COATED METAL GRAIN MATERIALS, SUCH AS FOR USE IN NUCLEAR REACTOR SYSTEMS, AND RELATED STRUCTURES AND SYSTEMS

(71) Applicant: NuScale Power, LLC, Portland, OR (US)

(72) Inventor: Frederick Botha, Corvallis, OR (US)

(21) Appl. No.: 17/966,090

(22) Filed: Oct. 14, 2022

Related U.S. Application Data
(60) Provisional application No. 63/255,868, filed on Oct. 14, 2021.

(51) Int. Cl. B22F 3/15; G21C 21/00; B22F 1/14; C23C 16/40; C23C 16/455

(52) U.S. Cl. CPC B22F 3/15; G21C 21/00; B22F 1/14; C23C 16/40; C23C 16/45525; B22F 2301/20; B22F 2302/25

(57) ABSTRACT

Methods of fabricating structures, such as parts for use in nuclear power generation systems, are described herein. A representative method of fabricating a part for a nuclear reactor system includes coating a plurality of particles of a powder of a first material with a second material, and then pressing and/or heating the coated powder into a monolithic structure. The second material can be substantially solidly insoluble with the first material such that, after pressing and/or heating, the particles of the first material define grains of the monolithic structure and the second material substantially encapsulates the grains in the monolithic structure. The first material can be susceptible to corrosion by a select process, and the second material can be resistant to corrosion by the select process such that the bulk first material of the monolithic structure is resistant to corrosion by the select process.

### CROSS-REFERENCE TO RELATED APPLICATION

This application claims the benefit of U.S. Provisional Patent Application No. 63/255,868, filed Oct. 14, 2021, and titled “COATED METAL GRAIN MATERIALS, SUCH AS FOR USE IN NUCLEAR REACTOR POWER CONVERSION SYSTEMS,” which is incorporated herein by reference in its entirety.

### TECHNICAL FIELD

The present technology is related to structures formed from powdered grain materials coated with a different material, such as a material substantially solidly insoluble with the powdered grain material, and methods of manufacturing structures from such coated powdered grain materials. The structures can be used as parts in, for example, nuclear reactor power conversion systems, heat exchangers, pressure vessels, metal smelter and crucible equipment, thermal barrier components and/or structural members, and/or other systems/devices intended to operate in high temperature and/or corrosive environments.

### BACKGROUND

Nuclear power conversion systems typically include multiple parts formed of metallic materials that need to have high strength, high corrosion resistance, a low (e.g., below-room-temperature) brittle to ductile transition temperature, high temperature creep resistance, and/or other specific material properties. Processes to fabricate such parts are demanding—typically involving multiple steps to produce parts with a desired microstructure to achieve the needed mechanical properties (e.g., yield strength and/or ductility). For example, fabrication of such parts can involve several steps including forging, heat treatment, and machining. These steps can be time-consuming, especially where the parts are large, e.g., reactor pressure vessel (RPV) shells. Likewise, in some fabrication processes, parts can be formed by pressing and sintering a material and then hot working the material to impart a desired (i) microstructure for increased high temperature strength, (ii) high temperature creep resistance, and/or (iii) low brittle to ductile transition temperature. The hot working step can limit the shape of material produced to stock in the form of rod, sheet, plate, and wire, which are then used to fabricate more complex parts. However, the fabrication of more complex parts can be limited by the need to start from plate, sheet, rod, and/or wire stock, and to weld such components together.

Additionally, some fabrication methods rely on coatings to protect against corrosion, thereby further complicating the fabrication process. More specifically, in applications where materials do not offer sufficient corrosion resistance, a part can be coated or cladded to prevent contact with a corrosive environment. Coating increases fabrication complexity and component cost. Further, coating or cladding failures can lead to subsequent equipment failure (e.g., boric acid corrosion for pressurized water reactors and oxidation of molybdenum alloys when exposed to air at elevated temperatures), and can therefore have significant safety and/or economic impacts that must be mitigated with stringent fabrication and/or operational controls.

### BRIEF DESCRIPTION OF THE DRAWINGS

Many aspects of the present technology can be better understood with reference to the following drawings. The components in the drawings are not necessarily to scale. Instead, emphasis is placed on clearly illustrating the principles of the present technology.

FIG. 1 is a partially schematic, partially cross-sectional view of a nuclear reactor system configured in accordance with embodiments of the present technology.

FIG. 2 is a partially schematic, partially cross-sectional view of a nuclear reactor system configured in accordance with additional embodiments of the present technology.

FIG. 3 is a flow diagram of a process or method for fabricating a part, such as one or more components of the nuclear reactor systems shown in FIG. 1 and/or FIG. 2, in accordance with embodiments of the present technology.

FIG. 4A is an enlarged view of a plurality of particles of a powder of a first material each with a coating of a second material thereon, for use in the method of FIG. 3, in accordance with embodiments of the present technology.

FIG. 4B is an enlarged view of a microstructure of a part formed using the method of FIG. 3 in accordance with embodiments of the present technology.

### DETAILED DESCRIPTION

Aspects of the present disclosure are directed generally toward methods of manufacturing structures, such as parts for use in nuclear power generation systems, and associated systems and devices. Such structures can be also be used as parts in heat exchangers, pressure vessels, metal smelter and crucible equipment, thermal barrier components and/or structural members, and/or other systems/devices intended to operate in high temperature and/or corrosive environments. In several of the embodiments described below, for example, a method of fabricating a part for a nuclear reactor system includes coating a plurality of particles of a powder of a first material with a second material, and then pressing and/or heating the coated powder into a monolithic structure. The second material can be substantially solidly insoluble with the first material such that, after pressing and/or heating, the particles of the first material define grains of the monolithic structure and the second material substantially surrounds/encapsulates the grains in the monolithic structure. The first material can be susceptible to corrosion by a select process, and the second material can be resistant to corrosion by the select process such that the bulk first material of the monolithic structure is resistant to corrosion by the select process.

In some embodiments, the pressing and/or heating process can form the part to have a net shape or near net shape to the desired final part and/or to have a microstructure that provides desired mechanical and/or chemical properties (e.g., ductility, strength, corrosion resistance, creep resistance, among others). In some aspects of the present technology, this can reduce or eliminate the need for further material working (e.g., hot or cold forming) and/or heat treatment to provide the desired final shape and microstructure of the part. Eliminating such steps can significantly reduce the time and complexity of fabricating parts. For example, conventional fabrication processes to form pressure vessels (e.g., light water reactor pressure vessel (RPV) shells) for nuclear reactor systems can take multiple years to fabricate to have the desired shape, material properties, and corrosion resistance. The processes to fabricate such parts are demanding—typically involving multiple steps to produce parts with a desired microstructure to achieve the needed mechanical properties (e.g., yield strength and/or ductility). For example, fabricating pressure vessels for nuclear reactor systems can include forging, heat treatment, machining, welding, assembly, testing, etc.

In some embodiments, the first material can comprise molybdenum and/or a molybdenum alloy. Conventional fabrication processes for forming molybdenum alloy components for high temperature applications (e.g., furnace components, hot isostatic pressing (HIP) components, high temperature nuclear reactor components) also require many complex and lengthy steps. For example, such conventional processes press and sinter a molybdenum material and then hot work the material to impart a desired (i) microstructure for increased high temperature strength, (ii) high temperature creep resistance, and/or (iii) low (e.g., below-room-temperature) brittle to ductile transition temperature. The hot working step can limit the shapes of material produced to stock in the form of rod, sheet, plate, and wire, which are then used to fabricate more complex parts. However, the fabrication of more complex parts can be limited by the need to start from the plate, sheet, rod, and/or wire stock and to weld such components together. In some embodiments of the present technology, parts can be manufactured from molybdenum and/or molybdenum alloy by pressing and/or heating molybdenum particles coated with a second material without requiring hot working and instead by forming parts to net shape or near net shape using a pressing and/or heating process on a coated powder material.

In additional aspects of the present technology, the second material does not diffuse into (e.g., form a solid solution with) the first material during or after pressing and/or heating because the second material is selected to have little or no solid solubility with the first material. Accordingly, the coating of the second material on the particles of the first material can function to fix the size of the grains in the final structure of the part to that of the size of the particles in the powder before pressing and/or heating, as the coating inhibits or even prevents growth of the grains during the pressing and/or heating process. Grain size has a measurable effect on many mechanical properties, such as strength (e.g., yield strength, fatigue strength, tensile strength, impact strength), hardness, and ductility, among others. For example, decreasing grain size typically increases the strength and ductility of a material. Accordingly, in some aspects of the present technology, limiting (e.g., minimizing) the size of the grains to the size of the particles used to form the part can increase the strength and the ductility of the final part.

In some embodiments, the second material further functions to protect the grains of the first material from corrosion by (i) being resistant to corrosion to which the first material is susceptible and (ii) encapsulating each of the grains in the monolithic structure. Accordingly, in some aspects of the present technology, a failure of the coating on an exposed surface of the part (or elsewhere on the part) due to mechanical abrasion, deformation due to the heating and/or pressing process, and/or other chemical or mechanical processes can result only in corrosion of the exposed grains without affecting the corrosion resistance of the overall part (e.g., the bulk first material).

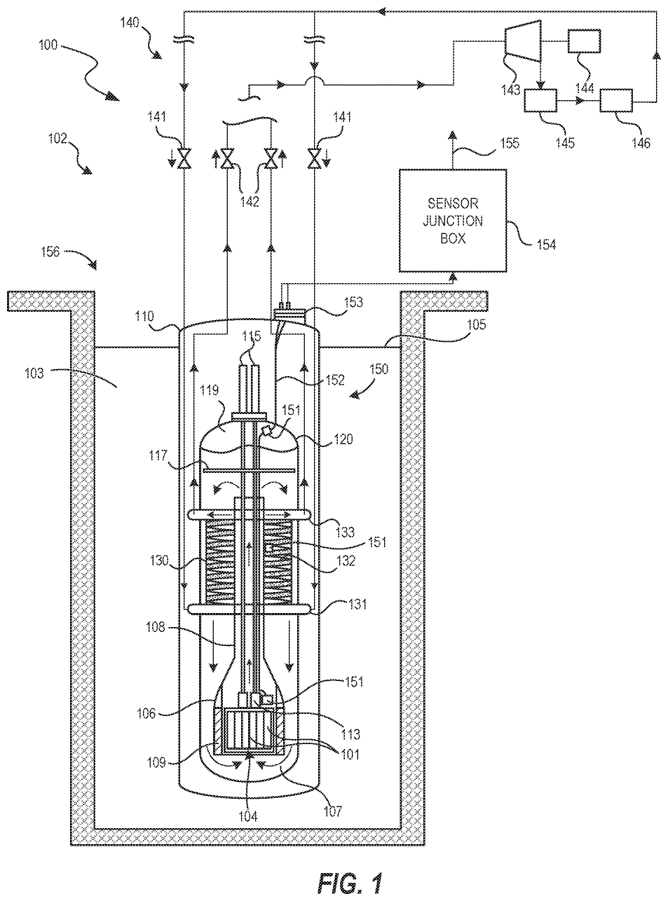

Certain details are set forth in the following description and in FIGS. 1-4B to provide a thorough understanding of various embodiments of the present technology. In other instances, well-known structures, materials, operations, and/or systems often associated with nuclear reactors, metallurgy processes, hot isostatic pressing (HIP) processes, and the like, are not shown or described in detail in the following disclosure to avoid unnecessarily obscuring the description of the various embodiments of the technology. Those of ordinary skill in the art will recognize, however, that the present technology can be practiced without one or more of the details set forth herein, and/or with other structures, methods, components, and so forth.

The terminology used below is to be interpreted in its broadest reasonable manner, even though it is being used in conjunction with a detailed description of certain examples of embodiments of the technology. Indeed, certain terms may even be emphasized below; however, any terminology intended to be interpreted in any restricted manner will be overtly and specifically defined as such in this Detailed Description section.

The accompanying Figures depict embodiments of the present technology and are not intended to limit its scope unless expressly indicated. The sizes of various depicted elements are not necessarily drawn to scale, and these various elements may be enlarged to improve legibility. Component details may be abstracted in the Figures to exclude details such as position of components and certain precise connections between such components when such details are unnecessary for a complete understanding of how to make and use the present technology. Many of the details, dimensions, angles and other features shown in the Figures are merely illustrative of particular embodiments of the disclosure. Accordingly, other embodiments can have other details, dimensions, angles and features without departing from the present technology. In addition, those of ordinary skill in the art will appreciate that further embodiments of the present technology can be practiced without several of the details described below.

To the extent any materials incorporated herein by reference conflict with the present disclosure, the present disclosure controls. The headings provided herein are for convenience only and should not be construed as limiting the subject matter disclosed.

### I. Select Embodiments of Nuclear Reactor Power Conversion Systems

FIG. 1 is a partially schematic, partially cross-sectional view of a nuclear reactor system 100 configured in accordance with embodiments of the present technology. The system 100 can include a power module 102 having a reactor core 104 in which a controlled nuclear reaction takes place. Accordingly, the reactor core 104 can include one or more fuel assemblies 101. The fuel assemblies 101 can include fissile and/or other suitable materials. Heat from the reaction generates steam at/in a steam generator 130, which directs the steam to a power conversion system 140. The power conversion system 140 generates electrical power, and/or provides other useful outputs. A sensor system 150 is used to monitor the operation of the power module 102 and/or other system components. The data obtained from the sensor system 150 can be used in real time to control the power module 102, and/or can be used to update the design of the power module 102 and/or other system components.

The power module 102 includes a containment vessel 110 (e.g., a radiation container) that houses/encloses a reactor vessel 120 (e.g., a reactor pressure vessel, or a reactor pressure container), which in turn houses the reactor core 104. The containment vessel 110 can be housed in a power module bay 156. The power module bay 156 can contain a cooling pool 103 filled with water and/or another suitable cooling liquid. The bulk of the power module 102 can be positioned below a surface 105 of the cooling pool 103. Accordingly, the cooling pool 103 can operate as a thermal sink, for example, in the event of a system malfunction.

A volume between the reactor vessel 120 and the containment vessel 110 can be partially or completely evacuated to reduce heat transfer from the reactor vessel 120 to the surrounding environment (e.g., to the cooling pool 103). However, in other embodiments the volume between the reactor vessel 120 and the containment vessel 110 can be at least partially filled with a gas and/or a liquid that increases heat transfer between the reactor vessel 120 and the containment vessel 110.

Within the reactor vessel 120, a primary coolant 107 conveys heat from the reactor core 104 to the steam generator 130. For example, as illustrated by arrows located within the reactor vessel 120, the primary coolant 107 is heated at the reactor core 104 toward the bottom of the reactor vessel 120. The heated primary coolant 107 (e.g., water with or without additives) rises from the reactor core 104 through a core shroud 106 and to a riser tube 108. The hot, buoyant primary coolant 107 continues to rise through the riser tube 108, then exits the riser tube 108 and passes downwardly through the steam generator 130. The steam generator 130 includes a multitude of conduits 132 that are arranged circumferentially around the riser tube 108, for example, in a helical pattern, as is shown schematically in FIG. 1. The descending primary coolant 107 transfers heat to a secondary coolant (e.g., water) within the conduits 132, and descends to the bottom of the reactor vessel 120 where the cycle begins again. The cycle can be driven by the changes in the buoyancy of the primary coolant 107, thus reducing or eliminating the need for pumps to move the primary coolant 107.

The steam generator 130 can include a feedwater header 131 at which the incoming secondary coolant enters the steam generator conduits 132. The secondary coolant rises through the conduits 132, converts to vapor (e.g., steam), and is collected at a steam header 133. The steam exits the steam header 133 and is directed to the power conversion system 140.

The power conversion system 140 can include one or more steam valves 142 that regulate the passage of high pressure, high temperature steam from the steam generator 130 to a steam turbine 143. The steam turbine 143 converts the thermal energy of the steam to electricity via a generator 144. The low-pressure steam exiting the turbine 143 is condensed at a condenser 145, and then directed (e.g., via a pump 146) to one or more feedwater valves 141. The feedwater valves 141 control the rate at which the feedwater re-enters the steam generator 130 via the feedwater header 131.

The power module 102 includes multiple control systems and associated sensors. For example, the power module 102 can include a hollow cylindrical reflector 109 that directs neutrons back into the reactor core 104 to further the nuclear reaction taking place therein. Control rods 113 can be used to modulate the nuclear reaction, and can be driven via fuel rod drivers 115. The pressure within the reactor vessel 120 can be controlled via a pressurizer plate 117 (which can also serve to direct the primary coolant 107 downwardly through the steam generator 130) by controlling the pressure in a pressurizing volume 119 positioned above the pressurizer plate 117.

The sensor system 150 can include one or more sensors 151 positioned at a variety of locations within the power module 102 and/or elsewhere, for example, to identify operating parameter values and/or changes in parameter values. The data collected by the sensor system 150 can then be used to control the operation of the system 100, and/or to generate design changes for the system 100. For sensors positioned within the containment vessel 110, a sensor link 152 directs data from the sensors to a flange 153 (at which the sensor link 152 exits the containment vessel 110) and directs data to a sensor junction box 154. From there, the sensor data can be routed to one or more controllers and/or other data systems via a data bus 155.

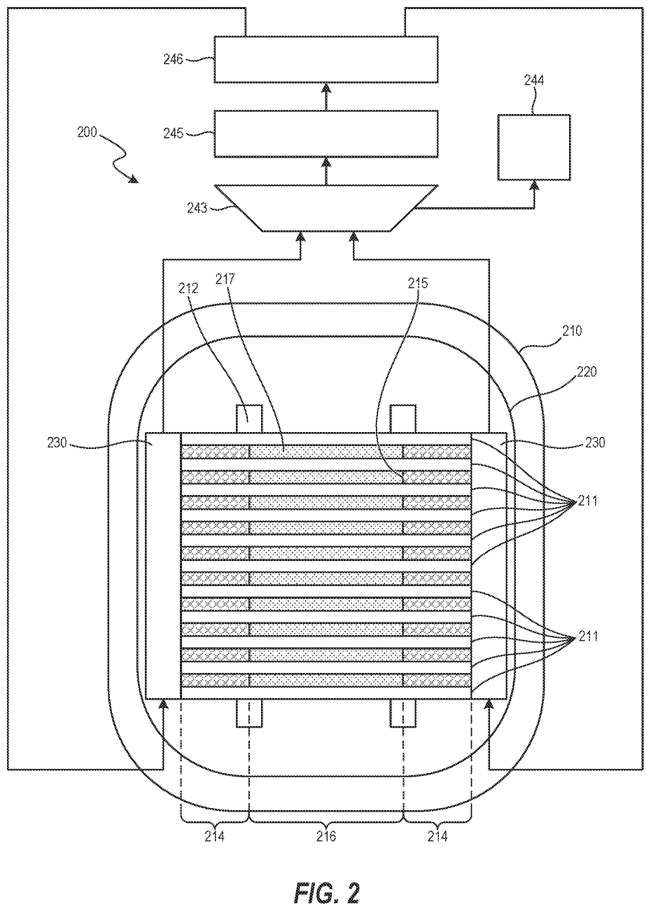

FIG. 2 is a partially schematic, partially cross-sectional view of a nuclear reactor system 200 (“system 200”) configured in accordance with additional embodiments of the present technology. In some embodiments, the system 200 can include some features that are at least generally similar in structure and function, or identical in structure and function, to the corresponding features of the system 100 described in detail above with reference to FIG. 1, and can operate in a generally similar or identical manner to the system 100. In some embodiments, the system 200 comprises a microreactor system.

In the illustrated embodiment, the system 200 includes a reactor vessel 220 and a containment vessel 210 surrounding/enclosing the reactor vessel 220. In some embodiments, the reactor vessel 220 and the containment vessel 210 are roughly cylinder-shaped or capsule-shaped. The system 200 further includes a plurality of heat pipe layers 211 within the reactor vessel 220. In the illustrated embodiment, the heat pipe layers 211 are spaced apart from and stacked over one another. In some embodiments, the heat pipe layers 211 are mounted/secured to a common frame 212, a portion of the reactor vessel 220 (e.g., a wall thereof), and/or other suitable structures within the reactor vessel 220. In other embodiments, the heat pipe layers 211 are directly stacked on top of one another such that each of the heat pipe layers 211 supports and/or is supported by one or more of the other ones of the heat pipe layers 211.

In the illustrated embodiment, the system 200 further includes a shield or reflector region 214 at least partially surrounding a core region 216. The heat pipes layers 211 can be circular, rectilinear, polygonal, and/or can have other shapes, such that the core region 216 has a corresponding three-dimensional shape (e.g., cylindrical, spherical). In some embodiments, the core region 216 is separated from the reflector region 214 by a core barrier 215, such as a metal wall. The core region 216 can include one or more fuel sources, such as fissile material, for heating the heat pipes layers 211. The reflector region 214 can include one or more materials configured to contain/reflect products generated by burning the fuel in the core region 216 during operation of the system 200. For example, the reflector region 214 can include a liquid or solid material configured to reflect neutrons and/or other fission products radially inward toward the core region 216. In some embodiments, the reflector region 214 entirely surrounds the core region 216. In other embodiments, the reflector region 214 partially surrounds the core region 216. In some embodiments, the core region 216 includes a control material 217, such as a moderator and/or coolant. The control material 217 can at least partially surround the heat pipe layers 211 in the core region 216 and can transfer heat therebetween.

In the illustrated embodiment, the system 200 further includes at least one heat exchanger 230 (e.g., a steam generator) positioned around the heat pipe layers 211. The heat pipe layers 211 can extend from the core region 216 and at least partially into the reflector region 214, and are thermally coupled to the heat exchanger 230. In some embodiments, the heat exchanger 230 is positioned outside of or partially within the reflector region 214. The heat pipe layers 211 provide a heat transfer path from the core region 216 to the heat exchanger 230. For example, the heat pipe layers 211 can each include an array of heat pipes that provide a heat transfer path from the core region 216 to the heat exchanger 230. When the system 200 operates, the fuel in the core region 216 can heat and vaporize a fluid within the heat pipes in the heat pipe layers 211, and the fluid can carry the heat to the heat exchanger 230.

In some embodiments, the heat exchanger 230 can be similar to the steam generator 130 of FIG. 1 and, for example, can include one or more helically-coiled tubes that wrap around the heat pipe layers 211. The tubes of the heat exchanger 230 can include or carry a working fluid (e.g., a coolant such as water or another fluid) that carries the heat from the heat pipe layers 211 out of the reactor vessel 220 and the containment vessel 210 for use in generating electricity, steam, and/or the like. For example, in the illustrated embodiment the heat exchanger 230 is operably coupled to a turbine 243, a generator 244, a condenser 245, and a pump 246. As the working fluid within the heat exchanger 230 increases in temperature, the working fluid may begin to boil and vaporize. The vaporized working fluid (e.g., steam) may be used to drive the turbine 243 to convert the thermal potential energy of the working fluid into electrical energy via the generator 244. The condenser 245 can condense the working fluid after it passes through the turbine 243, and the pump 246 can direct the working fluid back to the heat exchanger 230 where it can begin another thermal cycle.

In some embodiments, the nuclear reactor systems 100 and/or 200 can include some features that are at least generally similar in structure and function, or identical in structure and function, to any of the nuclear reactor systems described in (i) U.S. patent application Ser. No. 17/071,838, titled “HEAT PIPE NETWORKS FOR HEAT REMOVAL, SUCH AS HEAT REMOVAL FROM NUCLEAR REACTORS, AND ASSOCIATED SYSTEMS AND METHODS,” and filed on Oct. 15, 2020, (ii) U.S. patent application Ser. No. 17/071,795, titled “NUCLEAR REACTORS HAVING LIQUID METAL ALLOY FUELS AND/OR MODERATORS,” and filed on Oct. 15, 2020, (iii) U.S. patent application Ser. No. 17/404,607, titled “THERMAL POWER CONVERSION SYSTEMS INCLUDING HEAT PIPES AND PHOTOVOLTAIC CELLS,” and filed on Aug. 17, 2021, and/or (iv) U.S. patent application Ser. No. 17/479,932, titled “METHODS OF MANUFACTURING STRUCTURES FROM OXIDE DISPERSION STRENGTHENED (ODS) MATERIALS, AND ASSOCIATED SYSTEMS AND DEVICES,” and filed on Sep. 20, 2021, each of which is incorporated herein by reference in its entirety.

### II. Select Embodiments of Structures Formed from Coated Powdered Grain Materials and Methods of Manufacturing Structures from Coated Powdered Grain Materials

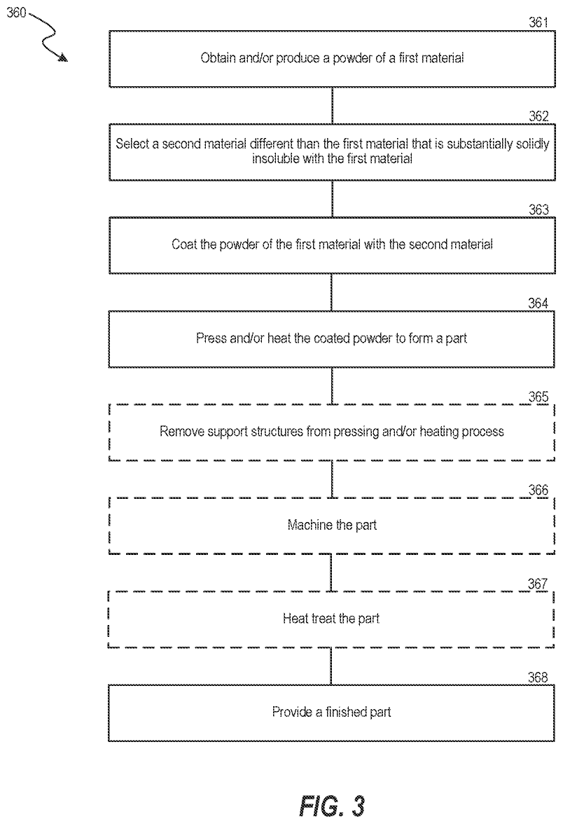

Referring to FIGS. 1 and 2 together, many of the components of the nuclear reactor systems 100 and 200 can be subject to high temperatures, high pressures, and/or corrosive environments during operation. Accordingly, in some embodiments it can be beneficial to manufacture some or all the components from materials that exhibit good corrosion resistance, mechanical properties, and/or creep resistance at high temperature. FIG. 3, for example, is a flow diagram of a process or method 360 for fabricating a part—such as one or more components of the nuclear reactor systems 100 and/or 200—in accordance with embodiments of the present technology. The part can also be used in, for example, heat exchangers, pressure vessels, metal smelter and crucible equipment, thermal barrier components and/or structural members, and/or other systems/devices intended to operate in high temperature and/or corrosive environments

At block 361, the method 360 can include obtaining and/or producing a powder comprising a first material (e.g., a first material powder). The first material powder can be referred to as a powdered grain material, a powdered metal grain material, and/or the like. In some embodiments, the first material is a metallic material. For example, the first material can comprise molybdenum, tungsten, iron, alloys thereof (e.g., titanium zirconium molybdenum (TZM), low alloy steels), and/or the like. In some embodiments, the powder is formed by atomizing a solid metal or metal alloy stock, metal oxide reduction, and/or another suitable process. In some embodiments, the powder can be porous—including both external exposed surfaces as well as internal exposed surfaces—such as when the power is formed by metal oxide reduction.

At block 362, the method 360 can include selecting a second material that is different than the first material, and that is substantially solidly insoluble in (e.g., has substantially no solid solubility with) the first material. As used herein, the term “substantially solidly insoluble” means that the second material has little or no solid solubility with the first material such that the first and second materials are practically insoluble with each other (e.g., unable to dissolve into one another and form a solid solution). In some embodiments, the second material comprises a ceramic material and/or a metallic material. For example, the second material can comprise ceria, yttria, lanthanum oxide, a carbide material, a nitride material, an oxide material, and/or the like. As described in greater detail below, selecting the second material to have little or no solid solubility with the first material can help inhibit or even prevent the second material from diffusing into the first material during subsequent processing steps.

In some embodiments, the second material can be selected based on a corrosion property of the first material. For example, the second material can be selected to resist corrosion by electrochemical and/or chemical actions that corrode the first material. That is, the first material can be susceptible to corrosion by a select process, and the second material can be resistant to corrosion by the same select process. For example, the first material can comprise a molybdenum alloy which is susceptible to corrosion via oxidation when exposed to air at elevated temperatures, and the second material can comprise a ceramic and/or other material that resists such oxidation at high temperatures. Likewise, the first material can comprise a material susceptible to corrosion via boric acid (e.g., when exposed to boric acid within a nuclear reactor system), and the second material can comprise a ceramic and/or other material that resists corrosion via boric acid. In other embodiments, the second material can be selected to be resistant to corrosion by liquid metals (e.g., bismuth, calcium, liquid uranium, iron) that can be present in, for example, a nuclear reactor system. In some embodiments, the first material can be selected based on desired material characteristics of the final part, and the second material can be selected to resist corrosion of the first material.

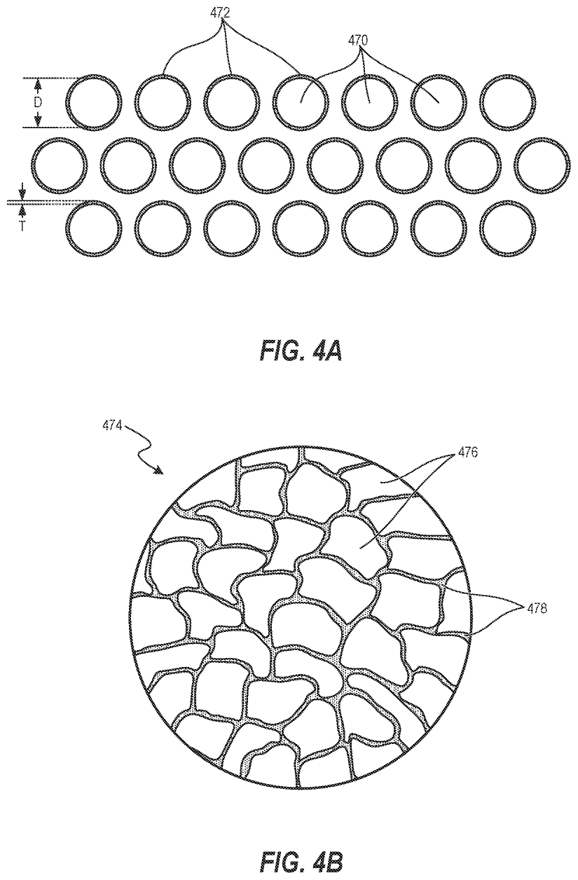

At block 363, the method 360 can include coating the first material powder with the second material. For example, the first material can be coated with the second material using an atomic layer deposition (ALD) process, a thin film deposition process, and/or another suitable process. The first material powder coated with the second material can be referred to as a coated powdered grain material, a coated powdered metal grain material, and/or the like. In some embodiments, each of particles (e.g., grains) of the first material powder are completely or substantially completely coated with the second material. FIG. 4A, for example, is an enlarged view of a plurality of particles 470 of the first material powder, each with a coating 472 of the second material thereon in accordance with embodiments of the present technology. In the illustrated embodiment, the coating 472 completely covers each of the particles 470 (e.g., an exposed outer/external surface of each of the particles 470). In some embodiments, where the particles 470 are porous, coating the particles 470 of the powder (e.g., via an ALD process) can include depositing the coating 472 on each of the particles 470 to cover or substantially cover the external exposed surface of each of the particles 470 as well as the internal exposed surfaces of each of the particles 470. That is, the coatings 472 can completely cover or substantially cover all the exposed surfaces of the particles 470. As used herein, the terms “substantially coated” or “substantially covered” mean that the second material covers/coats 100%, 90%-100%, or 80%-100% of the exposed surfaces of the particles 470 (e.g., both external exposed surfaces of the particles 470 and internal exposed surfaces of the particles 470 when the particles 470 are porous).

In some embodiments, the particles 470 can have a cross-sectional dimension D (e.g., a diameter, a width, a thickness) that is on a micrometer scale (e.g., between about 10-500 microns, between about 10-100 microns, between about 30-70 microns, between about 1-10 microns, between about 2-5 microns, about 30 microns) or sub-micrometer scale (e.g., between about 500-1000 nanometers), and the coating 472 on each of the particles 470 can have a thickness that is on a nanometer scale (e.g., between about 1-100 nanometers, between about 1-20 nanometers, between about 1-10 nanometers, less than 10 nanometers). Accordingly, the cross-sectional dimension D of the particles 470 can be significantly larger than the thickness of the coatings 472 thereon (e.g., between, about 50-200 times larger, between about 1000-10,000 times larger, between about 3000-7000 times larger, about 100 times larger, at least about 100 times larger, at least about 1000 times larger). As a result, in some embodiments of the present technology the total mass of the coatings 472 is small compared to the total mass of the particles 470—which can help minimize process costs associated with the coating process. In additional aspects of the present technology, the relatively small thickness of the coatings 472 (e.g., less than 10 nanometers) can result in coatings with an increased ductility. Such coatings can more readily deform without failure during subsequent processing steps (e.g., pressing steps).

At block 364, the method can include pressing and/or heating (e.g., sintering) the coated powder to form a desired part/structure, such as a part for use in a nuclear reactor power conversion system (e.g., one or more of the components of the nuclear reactor systems 100 and 200 described in detail above with reference to FIGS. 1 and 2). The part can be monolithic/integral—that is, a single piece/unit and formed without joints or seams. The coated powder can be pressed and/or heated using a press-and-sinter powder metallurgy process, a powder metallurgy hot isostatic pressing (PM-HIP) process, a cold HIP process, an injection molding and sintering process, and/or another suitable process. The pressing and heating steps can be separate or integrated into a single process. For example, using a press-and-sinter process, the powder can be inserted and then pressed in a die defining the shape of the desired part. The part can then be removed from the die and subsequently sintered. In some embodiments, using a PM-HIP process, the powder can be inserted in a metal canister that together with one or more support structures maintains the shape of the part during combined pressing and sintering in a hot isostatic pressing (HIP) system. In some embodiments, a vacuum is drawn on the canister to remove gas from the coated powder prior to the HIP process. In some embodiments, such a press-and-sinter and/or HIP process can form the part to have a net shape or near net shape to the desired final part, and/or to have a microstructure that provides desired mechanical and/or chemical properties (e.g., ductility, strength, corrosion resistance, creep resistance, and/or others). In some aspects of the present technology, this can reduce or eliminate the need for further material working (e.g., hot or cold forming) and heat treatment to provide the desired final shape and microstructure of the part.

In some aspects of the present technology, the second material does not diffuse into (e.g., form a solid solution with) the first material after pressing and/or heating because the second material is selected to have little or no solid solubility with the first material. FIG. 4B, for example, is an enlarged view of a microstructure 474 of the part after pressing and/or heating in accordance with embodiments of the present technology. In the illustrated embodiment, the pressing and/or heating process forms the coated powder particles together into a solid part having reduced porosity and increased density through a combination of plastic deformation, creep, and diffusion bonding. Specifically, referring to FIGS. 4A and 4B together, the coatings 472 on each of the particles 470 can bond together without diffusing into the particles 470 such that (i) the particles 470 define individual grains 476 of the first material in the microstructure 474 of the part and (ii) the coatings 472 form a fused encapsulant 478 of the second material around the grains 476 in the microstructure 474 of the part. That is, the encapsulant 478 of the second material can completely or substantially surround the grains 476 of the first material in the microstructure 474. As used herein, the terms “substantially surround” or “substantially encapsulate” that the encapsulant 478 covers/coats 100%, 90%-100%, or 80%-100% of the exposed surfaces of the grains 476 (e.g., both external exposed surfaces of the grains 476 and internal exposed surfaces of the grains 476 when the grains 476 are porous). In some embodiments, the thickness T (FIG. 4A) of the coatings 472 can be selected to be large enough such that the encapsulation 478 maintains coverage of the grains 476 after pressing and/or heating.

Accordingly, referring to FIGS. 4A and 4B together, the coatings 472 can function to fix the size of the grains 476 to that of the size of the particles 470 in the powder before pressing and/or heating, as the coatings 472 inhibit or even prevent growth of the grains 476 during the pressing and/or heating process. That is, individual ones of the particles 470 can form individual ones of the grains 476 in the part after pressing and/or heating without bonding or otherwise forming together such that the size (e.g., a first size) of the individual ones of the particles 470 in the powder is substantially the same as the size (e.g., a second size) of the individual ones of the grains 476 in the microstructure 474 of the part. In contrast, for example, if the particles 470 were pressed and heated without the coating 472 of the second material thereon, or if the second material were to have solid solubility with the first material, some or all of the particles 470 would bond together to form larger grains in the final part. Grain size has a measurable effect on many mechanical properties, such as strength (e.g., yield strength, fatigue strength, tensile strength, impact strength), hardness, and ductility, among others. For example, decreasing grain size typically increases the strength and ductility of a material. Accordingly, in some aspects of the present technology, limiting (e.g., minimizing) the size of the grains 476 to the size of the particles 470 used to form the part can increase the strength and the ductility of the final part. Furthermore, in some embodiments, after pressing and sintering, the part can comprise an oxide dispersion strengthened (ODS) material comprised of the first and second materials, which can exhibit good corrosion resistance, mechanical properties, and creep resistance at high temperature.

In some embodiments, the encapsulant 478 of the second material further functions to protect the first material of the grains 476 from corrosion. In particular, the second material can be resistant to the same type of corrosion that the first material is susceptible to. Accordingly, in some aspects of the present technology if the encapsulant 478 on an exposed surface of the part (or elsewhere on the part) fails due to mechanical abrasion, deformation due to the heating and/or pressing processes, and/or other chemical and/or mechanical processes, the result is corrosion of only the exposed grains 476 without affecting the corrosion resistance of the overall part (e.g., the bulk first material). That is, if the encapsulant 478 does not cover the entirety of one or more of the grains 476 in the final part that are exposed to a corrosive environment, only the exposed grains 476 are affected rather than the all the grains 476 in the part. For example, where the first material of the grains 476 comprises molybdenum or a molybdenum alloy, the second material of the encapsulant 478 can comprise ceria, yttria, lanthanum oxide, and/or materials that are resistant to oxidation at high temperatures (e.g., above 900° C.).

In contrast, current processes for imparting corrosion resistance to a material typically include coating (e.g., forming a cladding around) a manufactured part with a corrosion-resistant material. Because the coating is only on the outer exposed surface of the part, failure of the coating can expose the entire part to corrosion. The present technology not only inhibits or even prevents such bulk exposure of a part to corrosion (reducing or even eliminating safety and commercial risks associated with coating or cladding failure), but also does not require an additional step to coat or clad the part after pressing and/or heating—reducing fabrication cost and complexity. Moreover, because the coatings 472 are deposited (block 363) on the particles 470 prior to pressing and/or heating, the coatings 472 can inhibit or even prevent corrosion of the particles 470 before pressing and/or heating. In contrast, the powder used in current fabrication processes is susceptible to corrosion (e.g., oxygen uptake in the case of molybdenum or molybdenum alloy powder) after powder production that can degrade the properties of the of the powder.

Referring again to FIG. 3, at blocks 365-367 of the method 360, the part can optionally be further finished/completed to provide a finished part at block 368. For example, at block 365, the method 360 can optionally include removing one or more support structures used during the pressing and/or heating process (block 364) used to form the part. For example, when using a PM-HIP process, the canister can be removed along with any additional support structures used to prevent sagging of the part during the HIP process.

At block 366, the method 360 can optionally include further machining the part to net shape or near net shape (e.g., such that some machining and/or forming is needed to produce the final shape of the part). For example, blocks 361-364 of the method 360 can be used to fabricate plate, sheet, rod, wire, and/or other stock components that can be machined and joined together to form a more complex part. At block 367, the method 360 can optionally include heat treating the part to, for example, establish desired mechanical, performance, and/or durability properties depending on the specific part and application. For example, such heat treatment can alter the microstructure 474 (FIG. 4B) of the part to alter the hardness, formability, strength, abrasion resistance, etc., of the part.

However, such optional steps shown at blocks 365-367 are not necessary and, in some embodiments, a finished part can be fabricated via blocks 361-364 alone without additional forging, heat treatment, machining, and/or other similar steps. Eliminating such steps can significantly reduce the time and complexity of fabricating parts. For example, conventional fabrication processes to form pressure vessels (e.g., light water reactor pressure vessel (RPV) shells) for nuclear reactor systems (e.g., the containment vessel 110 and/or the reactor vessel 120 shown in FIG. 1, the containment vessel 210 and/or the reactor vessel 220 shown in FIG. 2) can take multiple years to form to have the desired shape, material properties, and corrosion resistance. The processes to fabricate such parts are demanding—typically involving multiple steps to produce parts with a desired microstructure to achieve the needed mechanical properties (e.g., yield strength and/or ductility). For example, the fabrication of pressure vessels for nuclear reactor systems can include forging, heat treatment, machining, cladding, welding, assembly, testing, etc. In some aspects of the present technology, such parts can be manufactured according to the method 360 much more quickly (e.g., in months rather than years) by omitting the machining, heat treatment, and forging steps and instead forming the parts to net shape or near net shape using a pressing and/or heating process on a coated powder material.

As another example, conventional fabrication processes for forming molybdenum alloy components for high temperature applications (e.g., furnace components, hot isostatic pressing (HIP) components, high temperature nuclear reactor components) also require many complex and lengthy steps. For example, such conventional processes press and sinter a molybdenum material and then hot work the material to impart a desired (i) microstructure for increased high temperature strength, (ii) high temperature creep resistance, and/or (iii) low brittle to ductile transition temperature. The hot working step can limit the shape of material produced to stock in the form of rod, sheet, plate, and/or wire, which are then used to fabricate more complex parts. However, the fabrication of more complex parts can be limited by the need to start from plate, sheet, rod, and/or wire stock and to weld such components together. Again, in some aspects of the present technology parts can be manufactured from molybdenum and/or molybdenum alloy according to the method 360 without requiring hot working and instead by forming parts to net shape or near net shape using a pressing and/or heating process on a coated powder material.

### III. Additional Examples

The following examples are illustrative of several embodiments of the present technology:
1. A method of forming a part, the method comprising:
pressing and/or heating a coated powder into a monolithic structure, wherein the coated powder comprises a plurality of particles of a first material coated with a second material different than the first material, wherein the second material is substantially solidly insoluble in the first material, wherein the particles of the first material define grains of the monolithic structure, and wherein the second material substantially encapsulates the grains in the monolithic structure.
2. The method of example 1, further comprising coating the particles of the first material with the second material.
3. The method of example 2 wherein coating the particles of the first material with the second material includes depositing the second material on the particles of the first material via an atomic layer deposition process.
4. The method of example 2 or example 3 wherein coating the particles of the first material with the second material includes depositing the second material on substantially an entire exposed surface of each of the particles of the first material.
5. The method of any one of examples 1˜4 wherein, before pressing and/or heating—
the particles of the first material have a cross-sectional dimension;
the second material coated on the particles of the first material has a thickness on individual ones of the particles; and
the cross-sectional dimension is at least 100 times larger than the thickness.
6. The method of any one of examples 1-5 wherein the first material comprises a metallic material, and wherein the second material comprises a ceramic material.
7. The method of any one of examples 1-6 wherein the first material comprises molybdenum, and wherein the second material comprises ceria, yttria, and/or lanthanum oxide.
8. The method of any one of examples 1-7 wherein the first material is susceptible to corrosion by a select process, and wherein the second material is resistant to corrosion by the select process.
9. The method of example 8 wherein the select process is oxidation from air at temperatures higher than 900° C.
10. The method of any one of examples 1-9 wherein the monolithic structure has a shape corresponding to a desired shape of the part.
11. The method of any one of examples 1-10 wherein pressing and/or heating the coated powder includes pressing and heating the coated powder in a hot isostatic pressing (HIP) process.
12. The method of any one of examples 1-10 wherein pressing and/or heating the coated powder includes pressing and heating the coated powder in a press-and-sinter process.
13. The method of any one of examples 1-12 wherein the particles of the first material have a first size before pressing and/or heating, and wherein the grains have a second size in the monolithic size that is substantially the same as the first size.
14. The method of any one of examples 1-13 wherein the part is a nuclear reactor part.
15. A part for a nuclear reactor, comprising:
a plurality of grains formed from a first material; and
a second material substantially encapsulating individual ones of the grains, wherein the second material is substantially solidly insoluble with the first material.
16. The part of example 15 wherein the first material comprises a metallic material, and wherein the second material comprises a ceramic material.
17. The part of example 15 or example 16 wherein the first material comprises molybdenum, and wherein the second material comprises ceria, yttria, and/or lanthanum oxide.
18. The part of any one of examples 15-17 wherein the first material is susceptible to corrosion by a select process, and wherein the second material is resistant to corrosion by the select process.
19. A part for a nuclear reactor formed according to a method, the method comprising:
pressing and/or heating a coated powder into a monolithic structure, wherein the coated powder comprises a plurality of particles of a first material coated with a second material different than the first material, wherein the second material is substantially solidly insoluble with the first material, wherein the particles of the first material define grains of the monolithic structure, and wherein the second material substantially encapsulates individual ones of the grains in the monolithic structure.
20. The part of example 19 wherein the first material comprises a metallic material susceptible to corrosion by a select process, and wherein the second material comprises a ceramic material resistant to corrosion by the select process.

### IV. CONCLUSION

The above detailed description of embodiments of the present technology are not intended to be exhaustive or to limit the technology to the precise forms disclosed above. Although specific embodiments of, and examples for, the technology are described above for illustrative purposes, various equivalent modifications are possible within the scope of the technology, as those skilled in the relevant art will recognize. For example, although steps may be presented in a given order, in other embodiments, the steps may be performed in a different order. The various embodiments described herein may also be combined to provide further embodiments.

From the foregoing, it will be appreciated that specific embodiments of the technology have been described herein for purposes of illustration, but well-known structures and functions have not been shown or described in detail to avoid unnecessarily obscuring the description of the embodiments of the technology. Where the context permits, singular or plural terms may also include the plural or singular term, respectively.

As used herein, the phrase “and/or” as in “A and/or B” refers to A alone, B alone, and A and B. Additionally, the term “comprising” is used throughout to mean including at least the recited feature(s) such that any greater number of the same feature and/or additional types of other features are not precluded. It will also be appreciated that specific embodiments have been described herein for purposes of illustration, but that various modifications may be made without deviating from the technology. Further, while advantages associated with some embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

I/We claim:

1. A method of forming a part, the method comprising:
pressing and/or heating a coated powder into a monolithic structure, wherein the coated powder comprises a plurality of particles of a first material coated with a second material different than the first material, wherein the second material is substantially solidly insoluble in the first material, wherein the particles of the first material define grains of the monolithic structure, and wherein the second material substantially encapsulates the grains in the monolithic structure.

2. The method of claim 1, further comprising coating the particles of the first material with the second material.

3. The method of claim 2 wherein coating the particles of the first material with the second material includes depositing the second material on the particles of the first material via an atomic layer deposition process.

4. The method of claim 2 wherein coating the particles of the first material with the second material includes depositing the second material on substantially an entire exposed surface of each of the particles of the first material.

5. The method of claim 1 wherein, before pressing and/or heating—
the particles of the first material have a cross-sectional dimension;
the second material coated on the particles of the first material has a thickness on individual ones of the particles; and
the cross-sectional dimension is at least 100 times larger than the thickness.

6. The method of claim 1 wherein the first material comprises a metallic material, and wherein the second material comprises a ceramic material.

7. The method of claim 1 wherein the first material comprises molybdenum, and wherein the second material comprises ceria, yttria, and/or lanthanum oxide.

8. The method of claim 1 wherein the first material is susceptible to corrosion by a select process, and wherein the second material is resistant to corrosion by the select process.

9. The method of claim 8 wherein the select process is oxidation from air at temperatures higher than 900° C.

10. The method of claim 1 wherein the monolithic structure has a shape corresponding to a desired shape of the part.

11. The method of claim 1 wherein pressing and/or heating the coated powder includes pressing and heating the coated powder in a hot isostatic pressing (HIP) process.

12. The method of claim 1 wherein pressing and/or heating the coated powder includes pressing and heating the coated powder in a press-and-sinter process.

13. The method of claim 1 wherein the particles of the first material have a first size before pressing and/or heating, and wherein the grains have a second size in the monolithic size that is substantially the same as the first size.

14. The method of claim 1 wherein the part is a nuclear reactor part.

15. A part for a nuclear reactor, comprising:
a plurality of grains formed from a first material; and
a second material substantially encapsulating individual ones of the grains, wherein the second material is substantially solidly insoluble with the first material.

16. The part of claim 15 wherein the first material comprises a metallic material, and wherein the second material comprises a ceramic material.

17. The part of claim 15 wherein the first material comprises molybdenum, and wherein the second material comprises ceria, yttria, and/or lanthanum oxide.

18. The part of claim 15 wherein the first material is susceptible to corrosion by a select process, and wherein the second material is resistant to corrosion by the select process.

19. A part for a nuclear reactor formed according to a method, the method comprising:
pressing and/or heating a coated powder into a monolithic structure, wherein the coated powder comprises a plurality of particles of a first material coated with a second material different than the first material, wherein the second material is substantially solidly insoluble with the first material, wherein the particles of the first material define grains of the monolithic structure, and wherein the second material substantially encapsulates individual ones of the grains in the monolithic structure.

20. The part of claim 19 wherein the first material comprises a metallic material susceptible to corrosion by a select process, and wherein the second material comprises a ceramic material resistant to corrosion by the select process.
